(19) United States
(12) Patent Application Publication
(10) Pub. No.: US 2019/0221525 A1
(43) Pub. Date: Jul. 18, 2019

(54) NEUTRON SHIELDING PACKING BODY FOR AIR TRANSPORTATION OF SEMICONDUCTOR DEVICE

(71) Applicant: SK hynix Inc., Icheon-si Gyeonggi-do (KR)

(72) Inventors: Kun Young LEE, Seoul (KR); Sang Jun LIM, Icheon-si Gyeonggi-do (KR); Ha Ni KIM, Hanam-si Gyeonggi-do (KR); Hyun Woo KIM, Seongnam-si Gyeonggi-do (KR); Jae Boem MUN, Cheongju-si Chungcheongbuk-do (KR); Sang Kil LEE, Cheongju-si Chungcheongbuk-do (KR)

(73) Assignee: SK hynix Inc., Icheon-si Gyeonggi-do (KR)

(21) Appl. No.: 16/237,521

(22) Filed: Dec. 31, 2018

(30) Foreign Application Priority Data
Jan. 18, 2018 (KR) 10-2018-0006454

(51) Int. Cl. H01L 23/552; B65D 65/38; B65D 25/04; G21F 1/02; H01L 21/677

(52) U.S. Cl. CPC H01L 23/552; B65D 65/38; H01L 21/677; G21F 1/02; B65D 25/04

(57) ABSTRACT

A neutron shielding packing body configured to pack a semiconductor device is disclosed. The neutron shielding packing body reduces Total Ionizing Dose (TID) defects caused in the semiconductor device by collisions with neutrons during air transportation of the semiconductor device. The neutron shielding packing body includes hydrogen and boron.

### CROSS-REFERENCE TO RELATED APPLICATION

The present application claims priority under 35 U.S.C. 119(a) to Korean patent application No. 10-2018-0006454, filed on 18 Jan. 2018, the disclosure of which is incorporated herein by reference in its entirety.

### BACKGROUND

Embodiments of the present disclosure relate to a neutron shielding packing body, and more particularly to a neutron shielding packing body configured to pack a semiconductor device, which may minimize Total Ionizing Dose (TID) defects caused by collision with neutrons generated during air transportation of the semiconductor device.

Cosmic rays may generate high-energy neutron radiation by colliding with nitrogen atoms or oxygen atoms in the atmosphere. Since neutrons are small in size, neutrons may pass through most materials, such as the human body, but the neutrons may sometimes collide with other atomic nuclei.

An amount of neutron radiation per unit time depends on altitude. For example, the amount of neutron radiation is proportional to altitude. The number of free neutrons (i.e., those neutrons not bound to a nucleus) at a flight altitude of between 30 thousand feet (kft) to 40 kft may be about 300 times greater than the number of free neutrons at ground level, such that the flight altitude of 30 kft˜40 kft may represent the greatest concentration of free neutrons. Neutrons are small in size and have no net electric charge, therefore the aluminum fuselage of an aircraft body offers little in the way of shielding. As a result, due to the small shielding effects of the aircraft body, free neutrons may pass into an aircraft and may collide with the atomic nuclei of semiconductor devices being transported by the aircraft, resulting in TID defects.

Due to a higher level of fabrication miniaturization in proportion to a higher degree of development of semiconductor fabrication technology, the neutron-caused TID effect affecting semiconductor devices continues to increase.

### SUMMARY

In accordance with an aspect of the present disclosure, a neutron shielding packing body for air transportation of a semiconductor device includes hydrogen and boron.

### BRIEF DESCRIPTION OF THE DRAWINGS

Features and advantages of the present disclosure will become readily apparent with reference to the following detailed description when considered in conjunction with the accompanying drawings.

FIG. 1 shows a perspective view illustrating a representation of an example of a neutron shielding packing body according to an embodiment of the present disclosure.

FIG. 2 shows a structural view illustrating a neutron shielding packing body, according to another embodiment of the present disclosure.

FIG. 3 shows a graph illustrating neutron shielding effects based on hydrogen (H) and thermal neutron shielding effects based on boron (B).

FIG. 4 shows a structural view illustrating a neutron shielding packing body, according to another embodiment of the present disclosure.

FIG. 5 shows a structural view illustrating a neutron shielding packing body, according to another embodiment of the present disclosure.

### DETAILED DESCRIPTION

Reference will now be made in detail to certain embodiments, examples of which are illustrated in the accompanying drawings. The terms used in the disclosure and claims should not be interpreted as having general or dictionary meanings. Instead, the terms should be interpreted as having meanings and associated concepts coinciding with the technical scope and sprit of the present disclosure based on the presented embodiments and appended claims. Embodiments described in the specification and shown in the drawings are purely illustrative and are not intended to be exhaustive. Various equivalent and modified embodiments are possible without departing from the scope spirit of the present teachings.

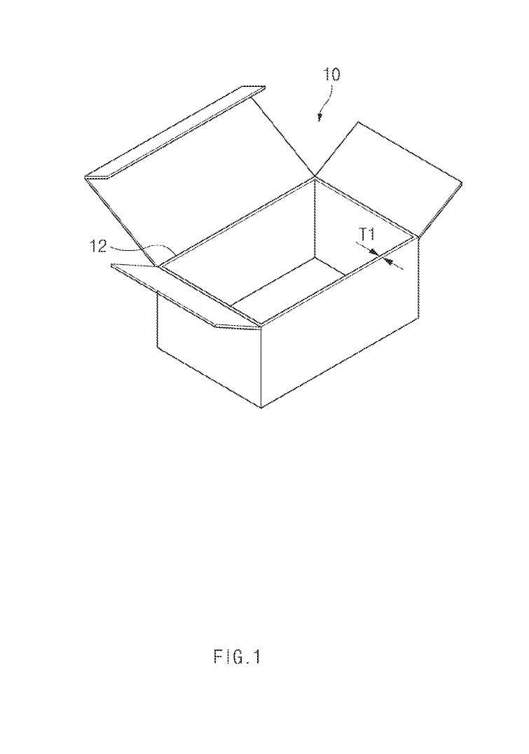

FIG. 1 shows a perspective view illustrating a neutron shielding packing body 10, according to an embodiment of the present disclosure.

The neutron shielding packing body 10 may be formed to include a rectangular parallelepiped outer box having an inner space in which contents, such as one or more semiconductor modules, can be placed. In more detail, if a top cover of the neutron shielding packing body 10 is folded inward along a line 12, then the rectangular parallelepiped outer box may be formed to have an inner space in which contents can be contained.

The neutron shielding packing body 10 may be formed of polyethylene or polypropylene containing a large amount of hydrogen contents. The neutron shielding packing body 10 may also be formed of other materials including a large amount of hydrogen and boron. For example, the neutron shielding packing body 10 may be formed of boron-added polyethylene or boron-added polypropylene.

As referred to herein, to form a component, such as an outer box, an outer wall, or a partition, to include hydrogen means that the component is made up of a material having molecules which include 50% or more of hydrogen atoms by number with respect to a total number of atoms included in the molecules. A component formed to include boron means the component includes a material, also referred to as a boron-added material, having molecules which include boron in any amount.

Hydrogen is an element similar in size and mass to a neutron which is expected to have the best neutron deceleration effect (e.g., neutron deceleration of about 50% or more) during a neutron-hydrogen collision. Therefore, the neutron shielding packing body 10 may be formed of polyethylene or polypropylene having a large amount of hydrogen acting as an efficient neutron deceleration means.

For some embodiments, boron is added to the polyethylene or polypropylene. This is to absorb thermal neutrons, which have already lost energy in collisions with hydrogen. The thermal neutrons are absorbed into the resultant boron, due to the higher neutron shielding effect of the added boron. That is, the neutron shielding packing body 10 may provide for collisions between neutrons and hydrogen, resulting in neutron deceleration. The decelerated neutrons (thermal neutrons) may be absorbed into the boron, providing for a higher neutron shielding effect.

For an embodiment, the neutron shielding packing body 10 may be formed to have a minimum thickness T1 of 3 millimeters (mm). The neutron shielding packing body may be formed to have a thickness of between 3 mm to 6 mm, for example. That is, considering that neutrons and hydrogen have a cross-sectional area of approximately 82 barns, the neutron shielding packing body thickness to statistically cause only one collision between neutron and hydrogen on the condition that polyethylene or polypropylene has density of 0.95 g/cm³ or less, may be calculated to be about 1.5 mm. In order to solve or mitigate TID defects, a minimal deceleration effect of about 75% is associated with an embodiment. To this end, a collision between a neutron and hydrogen needs to happen at least two times. Therefore, the neutron shielding packing body is taken to have a minimum thickness of 3 mm.

If a collision between a neutron and hydrogen has occurred four times, it is expected that the neutron energy will be reduced by about 90%, such that a thickness of the neutron shielding packing body may be set to 6 mm to statistically ensure four neutron-hydrogen collisions.

The neutron shielding effect increases in proportion to the thickness of the neutron shielding packing body 10, and the weight of the neutron shielding packing body 10 also increases in proportion to the thickness of the neutron shielding packing body 10, resulting in increased air transportation costs. In accordance with embodiments of the present disclosure, the thickness affecting shielding and the weight affecting transportation costs may be optimized, resulting in an acceptable number of TID defects with regard to neutrons at a reasonable weight with regard to transportation costs.

While embodiments disclosed above include a neutron shielding packing body 10 formed to include polyethylene or polypropylene containing a large amount of hydrogen, the present disclosure is not limited thereto. The neutron shielding packing body 10, for example, may be formed of titanium hydride (TiH₂) or zirconium(II) hydride (ZrH₂) containing a large amount of hydrogen. Although embodiments indicated above include boron added to polyethylene or polypropylene to produce a hydrogen-boron material, other embodiments allow for different materials, such as magnesium borohydride Mg(BH₄)₂ containing a large amount of hydrogen and boron.

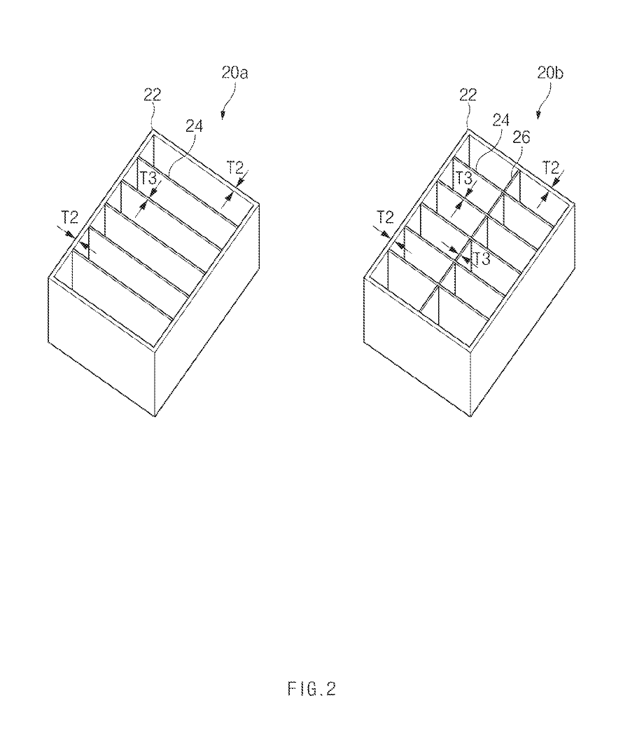

FIG. 2 shows a structural view illustrating the neutron shielding packing body 20a, 20b, according to another embodiment of the present disclosure.

Referring to FIG. 2, the neutron shielding packing body 20a, 20b may include an outer wall 22 and a plurality of partitions 24 and 26 formed within the outer wall 22, such that an inner space inside the outer wall 22 may be divided into a plurality of regions formed in a shape of a chest of drawers. Such a neutron shielding packing body may be inserted into a general outer box, and then used.

For an embodiment, the outer wall of the neutron shielding packing body 20a, 20b may be formed to have a thickness T2 of 6 mm, and each of the partitions 24 and 26 may be formed to have a thickness T3 of 3 mm. That is, statistically, neutrons may collide with hydrogen four times in the outer wall 200 of the neutron shielding packing body, and may additionally collide with hydrogen two more times in each partition 24 or 26, such that neutron deceleration of about 95% may occur on average.

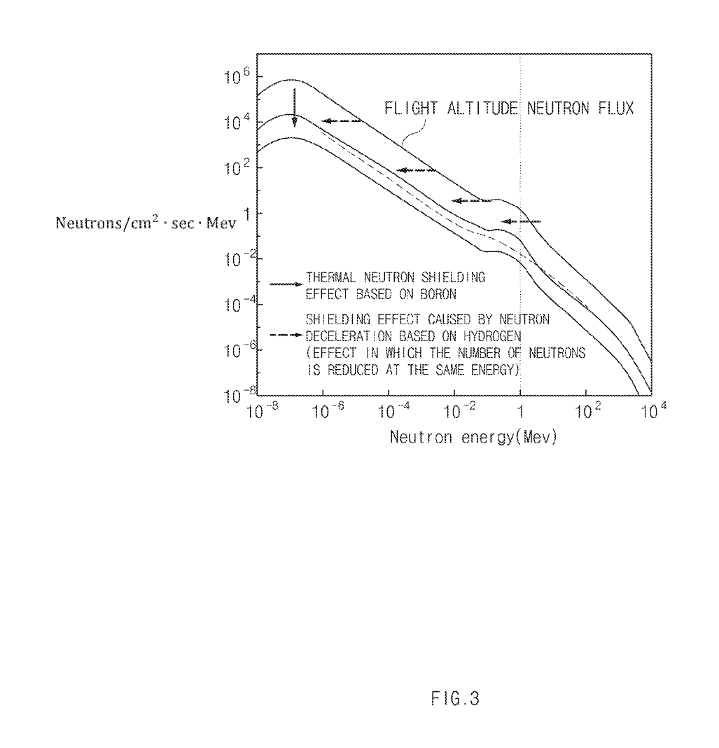

FIG. 3 shows a graph illustrating energetic neutron shielding effects based on hydrogen (H) and thermal neutron shielding effects based on boron (B).

A solid line located at the highest position of FIG. 3 indicates a line illustrating neutron flux at flight altitudes.

A dotted arrows indicate that neutron flux is reduced when a neutron collides with hydrogen four times using the neutron shielding packing body 10, 20a, 20b of the present teachings, and a solid arrow indicates that boron is additionally included in the neutron shielding packing body 10, 20a, 20b such that neutron flux acquired by a resultant boron-added neutron shielding packing body 10, 20a, 20b is much lower than neutron flux acquired by the neutron shielding packing body 10, 20a, 20b formed to have only hydrogen.

As illustrated in FIG. 3, it can be seen that neutrons collide with hydrogen four times using the neutron shielding packing body 10, 20a, 20b of the present teachings such that neutron flux is reduced by 90% or more. It can also be seen that boron is additionally included in the neutron shielding packing body 10, 20a, 20b such that neutron flux is reduced by about 95%.

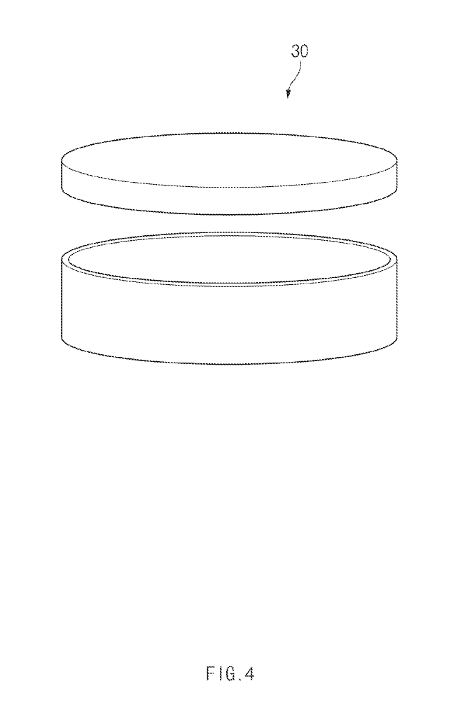

Although embodiments described with reference to FIG. 1 disclose a rectangular parallelepiped outer box for convenience of description and better understanding of the present disclosure, the present teachings are not limited to this shape. For example, a neutron shielding packing body 30 according to another embodiment may be formed in a cylindrical outer box, the shape of which is illustrated in FIG. 4.

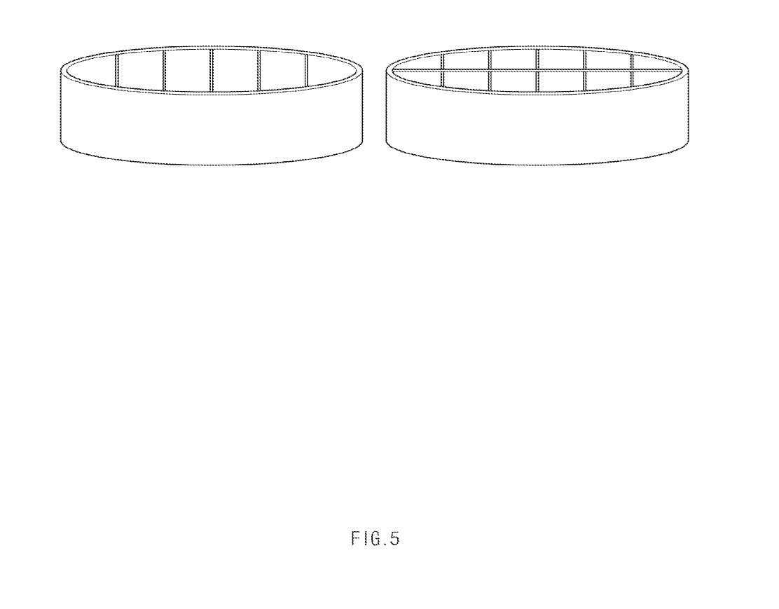

In addition, the outer wall of the neutron shielding packing body formed with a cylindrical chest-of-drawers shape inserted into the outer box is illustrated in FIG. 5.

As is apparent from the embodiments described above, the teachings of the present disclosure may reduce the number of TID defects caused by neutrons during air transportation of semiconductor devices.

Embodiments of the present disclosure may optimize the thickness of a packing body to provide acceptable neutron shielding at acceptable transportation costs. The shielding to weight ratio may be optimized given specific needs in terms of TID defect reduction and a transportation budget.

Those skilled in the art will appreciate that additional embodiments, different from those embodiments disclosed, which are faithful to the spirit and essential characteristics of the disclosure, are possible. Presented embodiments are therefore to be construed in all aspects as illustrative and not restrictive. The scope of the present disclosure should be determined by the appended claims and their legal equivalents, and not by the above description. Further, all changes coming within the meaning and equivalency range of the appended claims are intended to be embraced therein. In addition, it will be obvious to those skilled in the art that claims not explicitly presented may be added later with support from the detailed description and/or presented claims after the application is filed.

Although a number of illustrative embodiments have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings, and the accompanying claims. In addition to variations and modifications in the component parts and/or arrangements, alternative uses will also be apparent to those skilled in the art.

What is claimed is:

1. A neutron shielding packing body for air transportation of a semiconductor device, the neutron shielding packing body formed to include hydrogen and boron.

2. The neutron shielding packing body according to claim 1, wherein the packing body includes at least one of boron-added polyethylene, boron-added polypropylene, and magnesium borohydride Mg(BH₄)₂.

3. The neutron shielding packing body according to claim 2, wherein the packing body is formed to include an outer box having a top cover, and wherein the packing body has a thickness of between 3 millimeters and 6 millimeters.

4. The neutron shielding packing body according to claim 2, wherein the packing body is formed to include an outer wall and at least one partition disposed inside the outer wall, wherein the at least one partition divides the inside of the outer wall into a plurality of regions.

5. The neutron shielding packing body according to claim 4, wherein the outer wall has a thickness of between 5 millimeters and 7 millimeters, and wherein the at least one partition has a thickness of between 2 millimeters and 4 millimeters.

6. The neutron shielding packing body according to claim 5, wherein the outer wall has a thickness of approximately 6 millimeters, and wherein the at least one partition has a thickness of approximately 3 millimeters.
